(19) United States
(12) Patent Application Publication
(10) Pub. No.: US 2004/0177997 A1
(43) Pub. Date: Sep. 16, 2004

(54) Electronic apparatus

(76) Inventors: Hanae Hata, Yokohama-shi (JP); Tasao Soga, Hitachi-shi (JP); Toshiharu Ishida, Fujisawa-shi (JP); Kazuma Miura, Sanjo-shi (JP); Kanko Ishida, Fujisawa-shi (JP)

Correspondence Address: Robert C Colwell, Townsend and Townsend and Crew, Two Embarcadero Center, 8th Floor, San Francisco, CA, 94111-3438, US

(21) Appl. No.: 10/469,215

(22) PCT Filed: Apr. 12, 2002
(86) PCT No.: PCT/JP02/03676

(30) Foreign Application Priority Data
Apr. 18, 2001 (JP) 2001-119030

(51) Int. Cl. H05K 1/09

(52) U.S. Cl. 174/257; 174/260; 428/647

(57) ABSTRACT

It is an object of the present invention to provide an electronic device using completely new soldered connection, and more particularly to achieve flip chip bonding on a high temperature side in a temperature hierarchy connection as an alternative method for high Pb containing solder including a large mount of Pb. The object can be achieved by using a configuration in which metallic balls including a single metal, an alloy, a chemical compound or a mixture thereof are connected by Sn or In for pads between a chip and a substrate.

### FIELD OF THE INVENTION

The present invention relates to solder, and a connection method or an electronic device using the solder.

As Sn—Pb system solder, there is known eutectic solder consisting of 63 mass % Sn and 37 mass % Pb (hereinafter, which will be expressed without the term “mass %” with respect to the mass percentage of an element, for example, as “Sn-37Pb” in which the mass percentage of an element with no description of the composition ratio should be defined as the rest thereof) having a melting point of 183° C., which eutectic solder is widely used for manufacturing an electronic device. In addition, there are also known a Pb-rich type of Pb-5Sn (of which melting point is from 310 to 314° C.), Pb-10Sn (of which melting point is from 275 to 302° C.) and so on, which are generally called as “high lead containing solder” as being the solder with a high melting point. These types of solder are used by heating up to approximately 330° C., and thereafter Sn-37Pb having a low melting point is used so as not to melt the soldered part, thereby a temperature hierarchy connection can be achieved. Such a temperature hierarchy connection is applied to a type of a semiconductor device in which a chip is die-bonded, BGA (Ball Grid Array) and CSP (Chip Scale Package) in which a chip is flip-chip connected, etc. Especially, in the case of connecting a chip by the flip chip connection, the connection is made according to a method generally called as “C4 connection (Controlled Collapse Chip Connection)” using a solder bump between a pad of an electronic component, and a pad of a substrate.

The high lead containing solder allows not only the temperature hierarchy connection using Sn-37Pb for the reason of its melting point, but also has a property that the entire solder is soft because a large amount of soft lead is contained. This soft solder is suitable especially for a connecting portion of a chip because the connecting portion needs to have a property of reducing stress at a portion at which mechanical stress, etc. is generated due to a difference between thermal expansion coefficients of the chip and a substrate, and therefore, it has been possible to perform the flip-chip connection by using this soft high lead containing solder so as to solder a silicon chip directly on the substrate.

### SUMMARY OF THE INVENTION

However, out of consideration for environment, a lead-free solder material in which the lead is eliminated from the solder, and a soldering method using the lead-free solder material have been under development.

As a lead-free solder material for replacing the Sn-37Pb solder, there are proposed solder materials based on Sn—Ag system, Sn—Ag—Cu system, Sn—Cu system and Sn—Zn system, and a solder material including the above described materials, to which Bi or In is further added to reduce its melting point. On the other hand, as an alternate material for the type with a high melting point of high lead containing solder, Sn-5Sb (melting point: 232 to 240° C.) is the most promising solder material. However, when considering temperature variations, etc., in a substrate in a reflow furnace, it has been difficult to achieve the temperature hierarchy connection using the above described Pb-free solder material without melting the connecting portion consisting of Sn-5Sb. Au-20Sn (melting point: 280°) is also known, but this material is hard and costly, so that the use is limited. Especially for connecting materials having different thermal expansion coefficients, for example, for connecting a Si chip and a substrate or connecting a large Si chip, the Au-20Sn solder is not used because the solder is hard and its possibility of reducing stress is low, thereby the Si chip may be broken. Thus, as described in JP-A-11-172352, a Zn—Al system solder material containing Ge, Mg, etc., is proposed, recently. Because this material has a melting point of 280° C. to 380° C., it is suitable as an alternate material for the solder with a high melting point in view of the melting point. But the solder itself is hard and contains a large amount of Zn and Al having a high reactive property, and thus the influence of corrosion is feared.

Thus, it is an object of the present invention to provide an alternate material for solder including a large amount of lead and having a high melting point, as having been used for a pad in an electronic component, and a connection method and an electronic device using the solder material. It is especially intended to provide a lead-free material used for a barrel-shaped pad as called “C4 connection”, and a connection method using this material.

In order to solve the above described problems, the present invention provides a connecting portion between a pad of an electronic component and a pad of a substrate at which high lead containing solder has been used conventionally, as follows.

Firstly, the connecting portion is composed of metallic balls containing a single metal, an alloy, a chemical compound, or a mixture thereof, Sn or In solder, and an intermetallic compound generated by reaction between the Sn or In solder and the metallic balls, which metallic balls are connected by the intermetallic compound or by the solder and the intermetallic solder. In this specification, the metallic ball or a metallic ball phase is defined so as to mean a ball or a particle having a ball or particle shape and having at least a surface or an outer layer (that is, coating part) made of metal and/or intermetallic compound. That is, a metallic ball or metallic ball phase of which core is made of plastic or inorganic substance, etc., as well as metal, and of which surface or outer layer is coated with metal and/or intermetallic compound can be defined as the metallic ball.

Further, there is provided a construction in which metallic balls containing a single metal, an alloy, a chemical compound or a mixture thereof are connected by an intermetallic compound produced by reaction between at least one of Sn—Cu system solder, Sn—Ag system solder, Sn—Ag—Cu system solder, and solder based thereon but including at least one of In, Zn, Bi added thereto, and the solder balls, and/or by both the solder and the intermetallic compound.

The connection method will be described below.

A paste made up by mixing metallic balls containing a single metal, an alloy, a chemical compound or a mixture thereof and solder balls containing Sn or In is supplied between pads of an electronic component and a substrate, thereafter these are heated to melt the solder ball component to connect the metallic balls, the metallic balls and the pad of the electronic component, and the metallic balls and the pad of the substrate by the intermetallic compound produced by reaction between the solder and metallic balls and/or by both the solder and the intermetallic compound.

Further, a paste made up by mixing metallic balls containing a single metal, an alloy, a chemical compound or a mixture thereof, and at least one of Sn—Cu system solder, Sn—Ag system solder, Sn—Ag—Cu system solder, and solder based thereon to which at least one of In, Zn or Bi is added is supplied between pads of an electronic component and a substrate, thereafter these are heated to melt the solder ball component so as to connect the metallic balls, the metallic balls and the pad of the electronic component, and the metallic balls and the pad of the substrate by the intermetallic compound produced by reaction between the solder and the metallic balls and/or by both the solder and the intermetallic compound.

Here, the above described metallic ball is a ball containing Cu, Ag, Au, Al, Ni, Cu alloy, Cu—Sn compound, Ag—Sn compound, Au—Sn compound, Al—Ag compound, Zn—Al compound or a mixture thereof. Further, any one of Au plating, Ag plating, Sn single metal plating, alloy plating containing Sn, two-layer plating including Ni plating applied to a base and Au plating applied to the surface of the Ni plating, and two-layer plating including Ni plating applied to a base and Ag plating applied to the surface of the Ni plating can be applied on a surface of the metallic balls.

The pad has a barrel-shape, column-shape, rectangular parallelepiped shape or waist-shape.

Further, the electronic device as manufactured above is connected to other substrate using Pb-free solder.

Furthermore, for the substrate used in the electronic device as manufactured above, one with a metal core layer is used.

Other objects, features and advantages of the invention will become apparent from the following description of the embodiments of the invention taken in conjunction with the accompanying drawings.

### BRIEF DESCRIPTION OF THE DRAWINGS

FIG. 1 illustrates a mounting structure of the present invention;

FIG. 2 illustrates a configuration of a connecting portion between pads of the present invention;

FIGS. 3A-3B illustrate examples where the connecting portion is rectangular parallelepiped, column-shaped or waist-shaped;

FIGS. 4A-4E illustrate manufacturing steps of the electronic device shown in FIG. 1;

FIGS. 5A-5B illustrate manufacturing steps of the electronic device shown in FIG. 1;

FIG. 6 illustrates a situation in which a mixed paste before heating is supplied in the second step of the manufacturing steps shown in FIG. 4;

FIG. 7 illustrates an example where a flux component operates as underfill after the connection;

FIG. 8 illustrates an observation result of the connecting portion 5 by using an optical microscope;

FIG. 9 schematically illustrates the connecting portion 5;

FIG. 10 illustrates another example of the connecting portion between the pads of the present invention;

FIG. 11 illustrates manufacturing steps of a pad on a semiconductor chip according to the present invention;

FIGS. 12A-12H illustrate other manufacturing steps of the present invention;

FIG. 13 illustrates a connecting portion using polymer beads;

FIG. 14 illustrates an example where the present invention is used for a temperature layered connection;

FIG. 15 illustrates an example where the present invention is applied to an RF module; and

FIGS. 16A-16B illustrate an example where the heat spread characteristic is further improved in connection with the structure of the present invention.

### PREFERRED EMBODIMENTS OF THE INVENTION

A lead-free material, an electronic device and a connecting method according to the present invention will be described with reference to the drawings.

### Embodiment 1

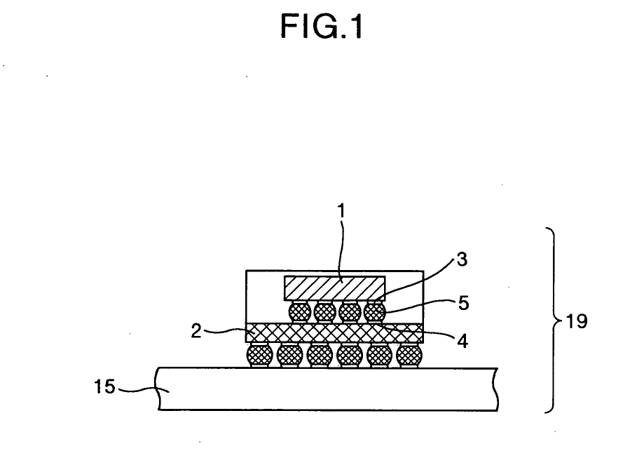

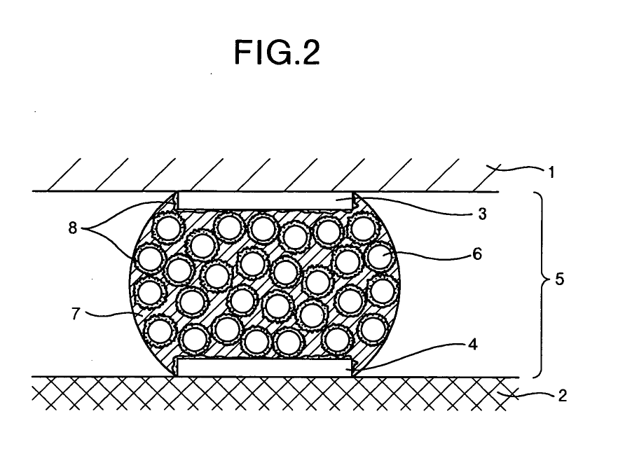

FIG. 1 shows an example of an electronic device to which the present invention is applied. In this mounting structure 19, an intermediate substrate 2 to which a semiconductor chip 1 is flip-chip connected is mounted on a printed circuit board 15. A sectional view of a connecting portion between the semiconductor chip 1 and the intermediate substrate 2 is shown in FIG. 2. The connecting portion 5 made up of a flip chip between a pad 3 of the semiconductor chip 1 and a pad 4 of the intermediate substrate 2 includes dispersed metallic ball phases 6 which are separate from one another. These metallic ball phases 6 are connected by a solder phase 7 and intermetallic compound phases 8 produced by reaction between the solder and the metallic balls. Further, the pad 3 of the semiconductor chip 1 and the metallic ball phases 6, and the pad 4 of the intermediate substrate 2 and the metallic ball phases 6 are also connected by the solder phase 7 and the intermetallic compound phase 8 produced by the reaction between the solder and the metallic balls.

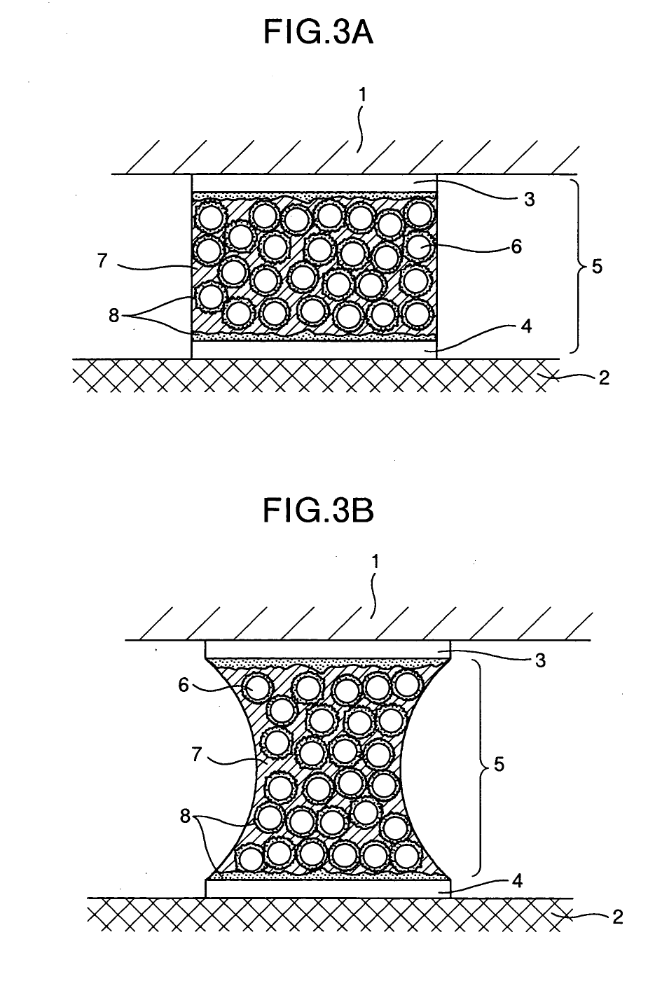

The connecting portion is barrel-shaped as shown in FIG. 1, but can also be rectangular parallelepiped or column-shaped as shown in FIG. 3A or waist-shaped with the narrowed central part as shown in FIG. 3B. In addition, though not shown, it can also be trapezoidal. In the case of rectangular parallelepiped or column-shaped connection shown in FIG. 3A, the mounting density can be increased in the height direction by reducing the thickness of the connecting portion. Therefore, LGA (Land Grid Array) connection using the shape in FIG. 2 is suitable for mounting of portable electronic devices such as cellular phone, digital video camera, notebook type personal computer, PDA (Personal Digital Assistant) of which important factors are miniaturization as well as thinning. The waist shape as shown in FIG. 3B can reduce stress generated at the connection ends. Furthermore, extending the distance between the pad 3 and the pad 4 makes it possible to extend the life of the device. Therefore, the waist-shaped connection in FIG. 3B is suitable for main frame computers, automobile electronic devices, etc., in which product life is very important. In any shape described in FIGS. 2 to 4, to further improve the life of the connecting portion, it is effective to disperse stress generated by differences in thermal expansion coefficient between the semiconductor chip 1 and the intermediate substrate 2, and it is recommendable to seal the space between the semiconductor chip 1 and the intermediate substrate 2 with resin. It is also effective to apply a resin top-coat onto the semiconductor chip 1. It is also possible to attach a radiating fin, etc., to the semiconductor chip 1 to dissipate heat generated in the dip 1.

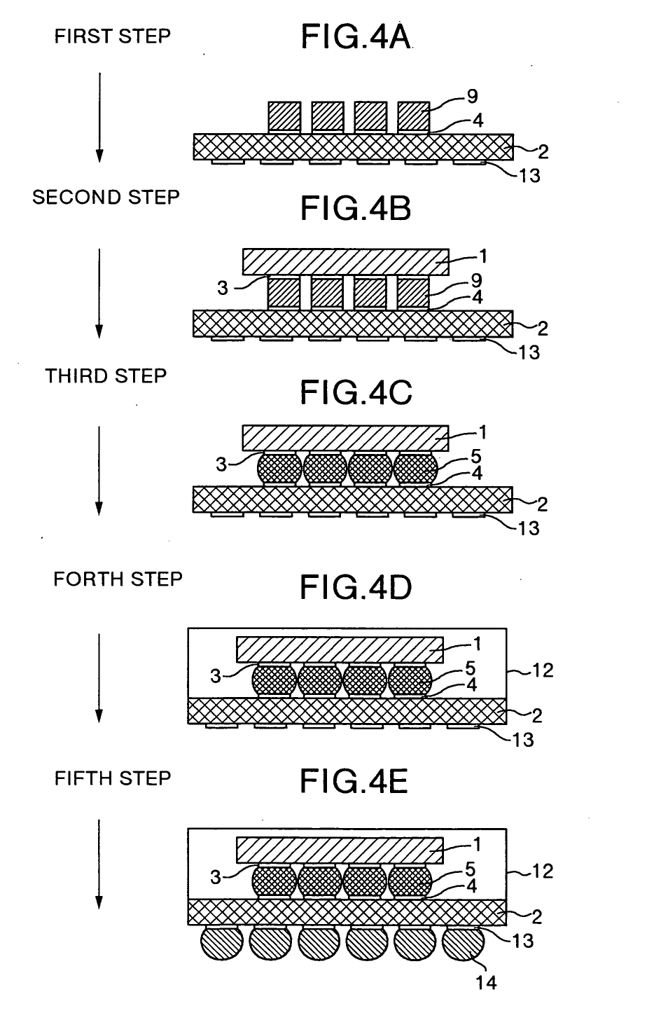

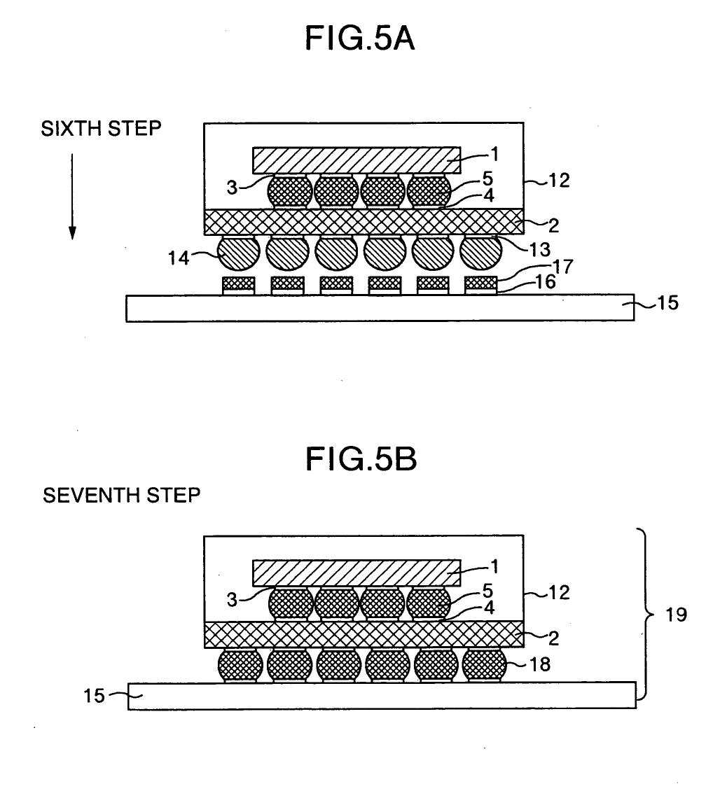

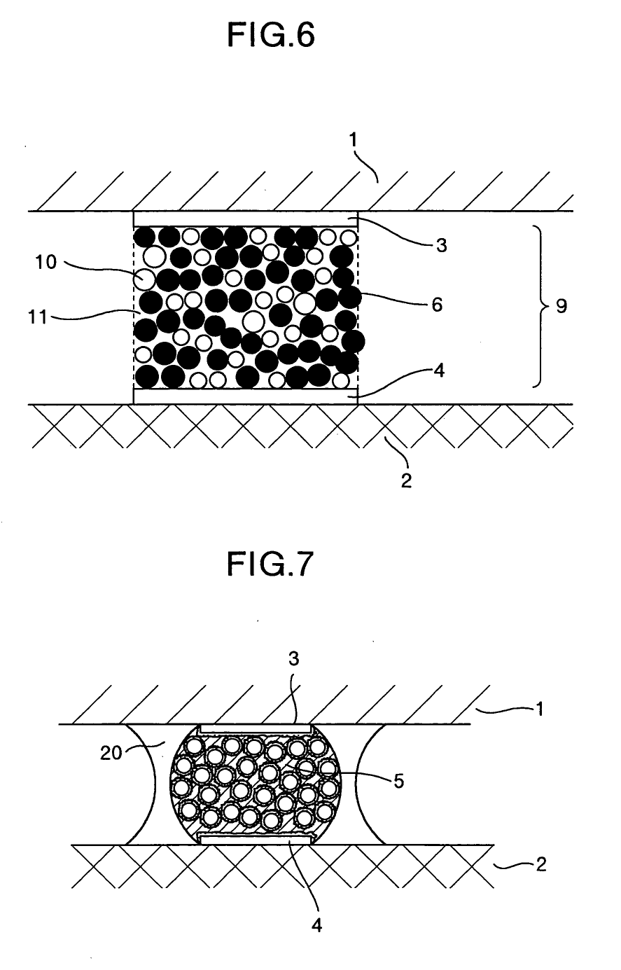

In the example of FIG. 2, the metallic ball phases 6 is made of Cu, solder phase 7 is made of Sn, and the intermetallic compound phase 8 produced by reaction between the metallic balls and the solder is made of a Cu—Sn intermetallic compound. The method of manufacturing the mounting structure 19 shown in this FIG. 1 will be explained using FIG. 4 and FIG. 5. In a first step, a mixed paste 9 is supplied to the pad 4 of the intermediate substrate 2 by means of printing, and in a second step the semiconductor chip 1 is mounted. FIG. 6 shows an enlarged view of the situation in which the mixed paste 9 is supplied. In the mixed paste 9, metallic balls 6 made of Cu and solder balls 10 made of Sn are mixed using a flux component 11. In a third step, these are subjected to reflow heating so that a connecting portion 5 is obtained. Then, in a fourth step, sealing resin 12 is used to seal the periphery of the chip. In a fifth step, solder balls 14 are supplied to pads 13 of the intermediate substrate 2 which are on the opposite side of the side on which the semiconductor chip 1 is mounted, and in a sixth step wiring lands 16 of a printed circuit board 15 are provided with receiving solder 17, and in a seventh step these are subjected to reflow heating so that the solder balls 14 and the receiving solder 17 are connected 18 and a mounting structure 19 is obtained.

Because Sn of the solder balls 10 needs to be melted, the heating temperature in the third step is preferably equal to or higher than the melting point 232° C. of Sn of the solder balls 10 while it depends on the size of the balls 10. However, in order to keep, after heating, the connecting portion at a higher temperature than the temperature during the connecting portion is formed, the reflow is performed at a temperature sufficiently higher than the melting point of Sn, that is, a maximum temperature of 280° C. Since it is necessary to melt Sn and secure wetting with Cu, both RMA (Rosin mildly activated) and RA (Rosin activated) may be used for the flux component 11 of the paste. However, at this time, a rosin system RMA type is used therefor. The ambient gas can be air, but an inert gas such as nitrogen is used to improve wettability between Cu and Sn. The RMA type is suitable for a mounting structure difficult to be cleaned, for example, structure with very narrow pitch or a structure for which cleaning is possible but cleaning residue becomes rather problematic. In this case, the activity is weak and therefore it is preferable to perform the connection in an inert atmosphere such as nitrogen. The RA type is preferable for the structure for which cleaning is possible. In this case, connecting is also possible in the air. Furthermore, it is also possible to use the flux, which can be used as underfill after the connection. It is preferable that this underfill cover completely between the semiconductor chip 1 and the intermediate substrate 2 for the sake of improvement of the life of the connecting portion. However, as shown in FIG. 7, even if only the periphery of the pads is covered with resin 20, stress concentration at the connecting ends can be reduced and it is therefore effective for improvement of the life of the connecting portion.

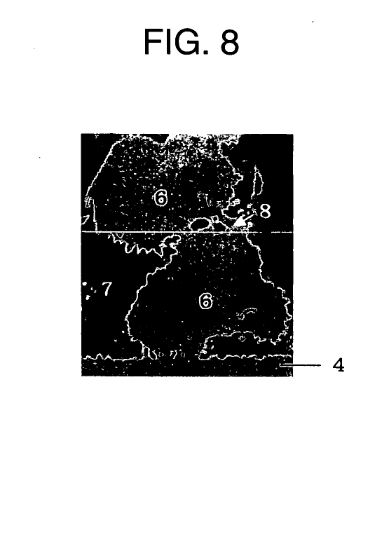

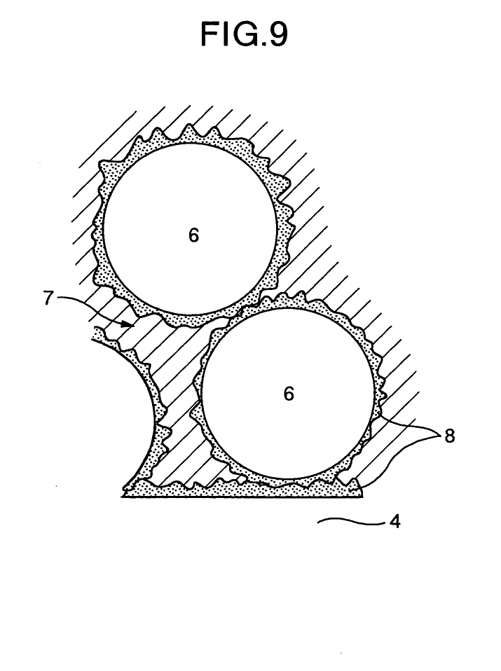

Thus, when the structure shown in FIG. 6 is heated, Sn of the solder balls 10 is melted and the intermetallic compound is formed on the interface to Cu of the metallic balls 6, and the metallic ball phases 6 of Cu are connected to one another. A result of observation of the connecting portion 5 using an optical microscope at this time is shown in FIG. 8 and a schematic view thereof is shown in FIG. 9. A layer of the intermetallic compound 8 of Cu and Sn is formed in the interface. Further, melted Sn also forms an intermetallic compound with the pad 3 of the semiconductor chip 1 and the pad 4 of the intermediate substrate 2, and therefore the metallic ball phases 6 of Cu are connected with the pad 3 and the pad 4. In this way, the pad 3 of the semiconductor chip 1 and the pad 4 of the intermediate substrate 2 are connected. By the formation of these compound layers, it is therefore possible to keep strength even at a high temperature of 250° C. or above. Finally, in the connecting portion 5 in FIG. 1, a part of Sn of the solder balls 10 becomes a Cu—Sn intermetallic compound (Cu6Sn5, melting point: approximately 630° C.), the melting point of the connecting portion and its periphery is increased. Even if the remaining Sn is melted, unless the other part is melted, it is possible to secure strength enough to withstand the process of subsequent soldered connections.

Further, since Cu is soft, strain generated between a part and the substrate can be modified to a certain degree inside Cu which remains in the connecting portion, and this method can be used for the connecting portion as a substitute for the connecting portion using high lead containing solder. Therefore, considering thermal fatigue resistance of a soldered joint portion, when the distance between the mutually separated Cu metallic balls 6 is extremely short, the contact portion may become an intermetallic compound, but when the distance is normal, it is preferable that Sn and Cu remain there from the standpoint of ease of modification. That is, in the final connecting portion 5, the thermal fatigue resistant is improved when the proportion of hard compounds is small and the proportion of metallic ball phases 6 made of easily modifiable Cu is large, and therefore it is preferable to bring the Cu metallic balls close to contact with one another by adjusting at least one of the amount of Sn to be melted, duration of melting and melting temperature in the sense that the metallic ball phases 6 are connected to each other by the intermetallic compounds.

Therefore, for an electronic device having the connecting portion shown in FIG. 2, temperature hierarchy connection conventionally carried out using Sn—Pb system solder is available in the subsequent steps. This joint is not melted at a soldering temperature of approximately 250° C. and its joint is kept, and therefore the joint will not be peeled off when the device is mounted on the circuit substrate later. Accordingly, in the subsequent steps, it becomes possible to carry out the temperature hierarchy connection with respect to another substrate by using a Pb-free solder material such as Sn—Cu system, Sn—Ag system, Sn—Ag—Cu system, Sn—Cu system, Sn—Zn system and those solder to which Bi and/or In is further added to make the melting point down, instead of using the Sn—Pb system solder, in consideration of the environment.

Here, Cu is used for the metallic balls 6 in FIG. 1, but the material is not limited to Cu, and it is also possible to use Ag, Au, Al, Ni, Cu alloy, Cu—Sn compound, Ag—Sn compound, Au—Sn compound, Al—Ag compound or Zn—Al compound. Au has good wettability and has the effect of reducing a void in the connecting portion. Furthermore, Au itself is soft and appropriate for reduction of stress. On the other hand, Al itself is not only soft and appropriate for reduction of stress, but also cheaper than Au.

Further, it is also possible to apply to the surface of the metallic balls 6 any one of Au plating, Ag plating, Sn single metal plating, alloy plating including Sn or double-layer plating including Ni plating applied to a base and Au plating applied to the surface of the Ni plating, or including Ni plating applied to the base and further Ag plating applied to the surface of the Ni plating, thereby the wettability and strength are improved. The merit of double-layer plating is high conservation stability. Improving the wettability has the effect of reducing a void in the connecting portion. Further, applying the plating processing causes the melted solder to easily get wet and spread over the metallic balls 6, which allows the metallic balls 6 to be spaced more uniformly. Adding a trace of Bi, etc., of 1 mass % or more to Sn has the effects of improving fluidity of solder and of improving its wettability on the terminals. However, the content of Bi exceeding 5 mass % leads to fragile, which is not desirable.

In order to reduce thermal expansion of the entire connecting portion 5, it is also possible to use invar, silicon oxide (SiO₂), aluminum oxide (Al₂O₃), aluminum nitride, silicon carbide, etc., for the metallic balls 6, and use a mixed paste 9 spread uniformly by applying metallization to cause the surface to get wet with solder or applying plating with Sn or In, etc., or solder plating.

Further, in a combination whereby large strain occurs in the connecting portion, it is also possible to additionally mix plastic balls or use plastic balls independently. As the material of these plastic balls, it is possible to use polyimide, heat resistant epoxy, silicon, various polymer beads or metamorphosed versions of these materials, and use the mixed paste 9 obtained by mixing the plastic balls subjected to metallization to cause the surface to get wet with solder with other metallic balls or uniformly spreading the plastic balls independently to reduce rigidity of the connecting portion 5.

The metallic balls 6 need not always be spherical, but can also have considerably uneven surfaces, or be of a mixture of a bar shape, dendrite shape or rectangular shape. The advantage of the spherical shape is its printing properties and it is preferable to use the spherical shape for connection in narrow pitch. The advantage of an dendrite crystal, etc., is that there are many adjacent contacts among dendrite crystals (conjuncture among Cu portions increases the number of compound joints), which requires only a smaller amount of metal, secures strength at a high temperature and is expected to improve thermal fatigue resistant. For this reason, it is considered ideal that the dendrite crystals are connected by contacts and move in an elastic fashion. Therefore, there can also be a method to wrap Cu dendrite crystals with Sn, etc., to make them spherical, mix them with the paste components and use them as mixed pastes.

In the example in FIG. 2, Sn is used for the solder balls 10, but it is also possible to use Sn—Cu system solder, Sn—Ag system solder or Sn—Ag—Cu system solder. When Cu is introduced into Sn, the melting point is lowered, and when the metallic balls 6 made of Cu are used, it is possible to suppress dissolution of Cu from the metallic balls 6. Ag also has the effect of lowering the melting point. Using one or more of solders in which at least one of In, Zn and Bi is added thereto will further lower the melting point and can decrease the connecting temperature in the third step in FIG. 4. Further, besides Sn system solder, it is also possible to use In which can lower the connecting temperature.

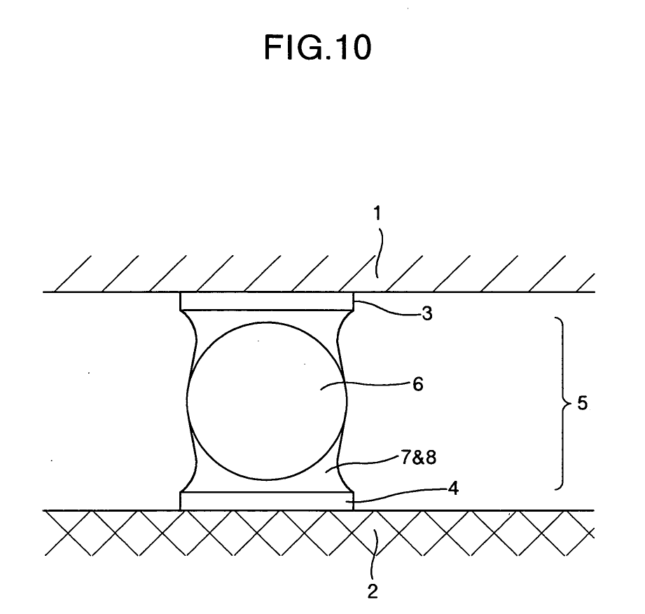

When the metallic balls 6 and solder balls 10 in the mixed paste 9 are too small, the wettability decreases, and therefore it is particularly desirable that the solder is 1 μm or greater. Finally, since it is necessary to achieve a structure with the pad having at least one metallic ball as shown in FIG. 10, the upper limit depends on the shape of the pad. Since a single metallic ball occupies a large area of the connecting portion in this structure, the metallic balls using Cu, for example, have very high thermal conductivity, and thus, it can be expected to have a high heat radiation characteristic.

The reflow is performed at 280° C. which is a maximum temperature, but when a large part of Sn of the solder balls 10 remains, this can be solved by further increasing connecting temperature to relatively increase the amount of an intermetallic compound. It is also possible to provide an aging process after the connecting to let the intermetallic compound grow to reduce the amount of Sn. However, when the aging is performed for too a long time at a high temperature, Cu3Sn compounds grow on the Cu side. The mechanical property of Cu3Sn is hard and fragile, and therefore from the standpoint of securing strength it is desirable to control Cu3Sn to prevent it from growing. Increasing the connecting temperature as much as possible will eliminate the need for subsequent steps of the aging.

In any case, the connection method according to this embodiment can reduce the connecting temperature compared to conventional high lead containing solder, and can thereby reduce heat damage to the semiconductor chip 1 and the intermediate substrate 2. It is possible to use not only a Si chip, and a GaAs chip but also CSP, BGA, etc., for the semiconductor chip 1. For the intermediate substrate 2, an organic substrate such as glass epoxy is generally used, but when high density mounting is required, a buildup substrate, etc., is used. Further, for electronic devices for automobiles, etc., which require high heat resistance, ceramic substrates, etc., can be used. Furthermore, when a heat radiation characteristic through a substrate is required, a metal core substrate is suitable.

### Embodiment 2

In Embodiment 1, the mixed paste 9 is supplied and connected by printing it on the intermediate substrate 2 and reflowing it. Other methods will be explained here.

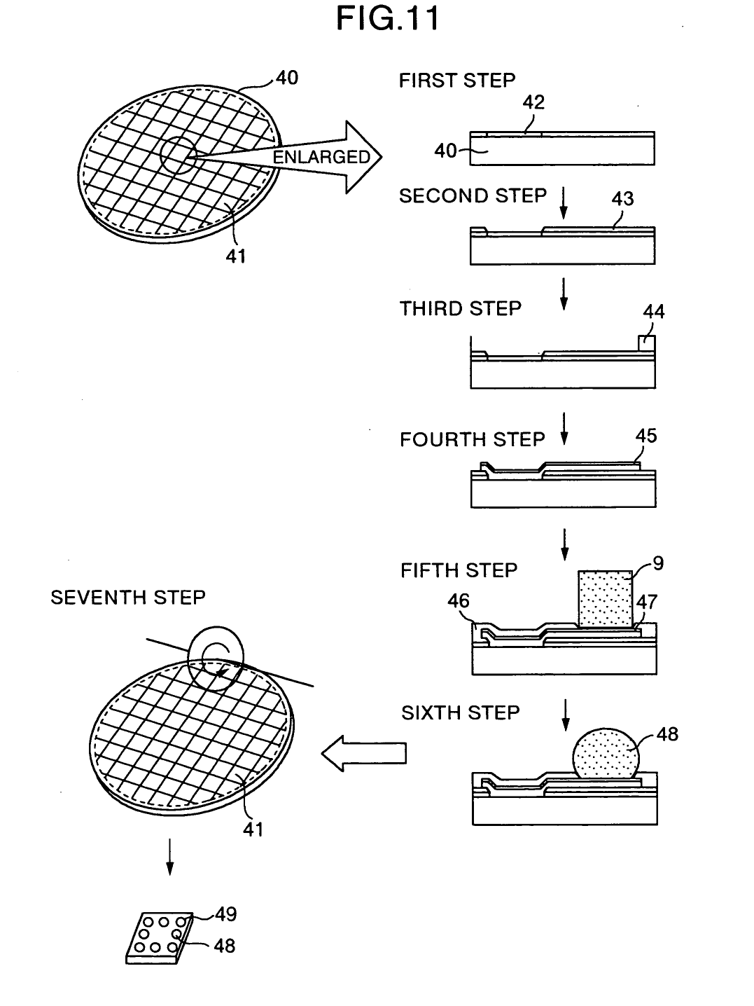

As is generally called “WL-CSP (Wafer Level Chip Size Package)”, a bump is created beforehand on a pad of each chip 41 which is constructed in a wafer 40 form. These manufacturing steps will be shown in FIG. 11. Firstly, a pad 42 such as Al and Al—Cu alloy is formed on a wafer 40 of Si, etc., by sputtering or etching, and then in a second step, the entire surface of a surface protection film 43 is coated using a polyimide or silicon nitride film, and then an opening is formed on the pad 42. In the following third step, a photoresist 44 is supplied to a necessary part, and in a fourth step a metal multilayer film 45 made of Cr/Cu/Ni or Cr/Cu/Au, etc., is formed, and in a fifth step a surface protection film 46 is further formed on a necessary part to obtain a rewired pad 47. It is also possible to form a layer of Au, etc., on the pad 47 to improve wettability. By supplying a mixed paste 9 on this pad 47 by means of printing, and by heating it in a sixth step, a bump 48 is obtained. Then, in a seventh step, dicing is performed to form the size of each chip 49 to obtain a Si chip 49 having the bump. This chip 49 is mounted on an intermediate substrate by face-down, and then is connected by means of reflow heating, or a pressurizing and heating method.

In addition to the printing using an adhesive paste containing flux as in the case of the above-described embodiment, a method of supplying this mixed paste 9 using a dispenser is also available. When the mixed paste is supplied to a high density pad of 100 μm pitch, if the diameter of the pad is approximately 50 μm, it is preferable that the diameter or size of the metallic ball 6 and the solder ball 10 are approximately 1/10 of the diameter of the pad, that is, approximately 5 μm. Therefore, in the case of a paste which is obtained by mixing Cu and solder balls of 3 to 8 μm in diameter, unevenness due to the particle diameter is not noticeable with respect to the diameter of the bump. Cu mixed with fine particles can be reduced using rosin, but Sn ball fine particles cannot be reduced easily even if using rosin, and therefore, it is recommendable to use it transformed into RMA type flux containing a certain amount of activator such as halogen.

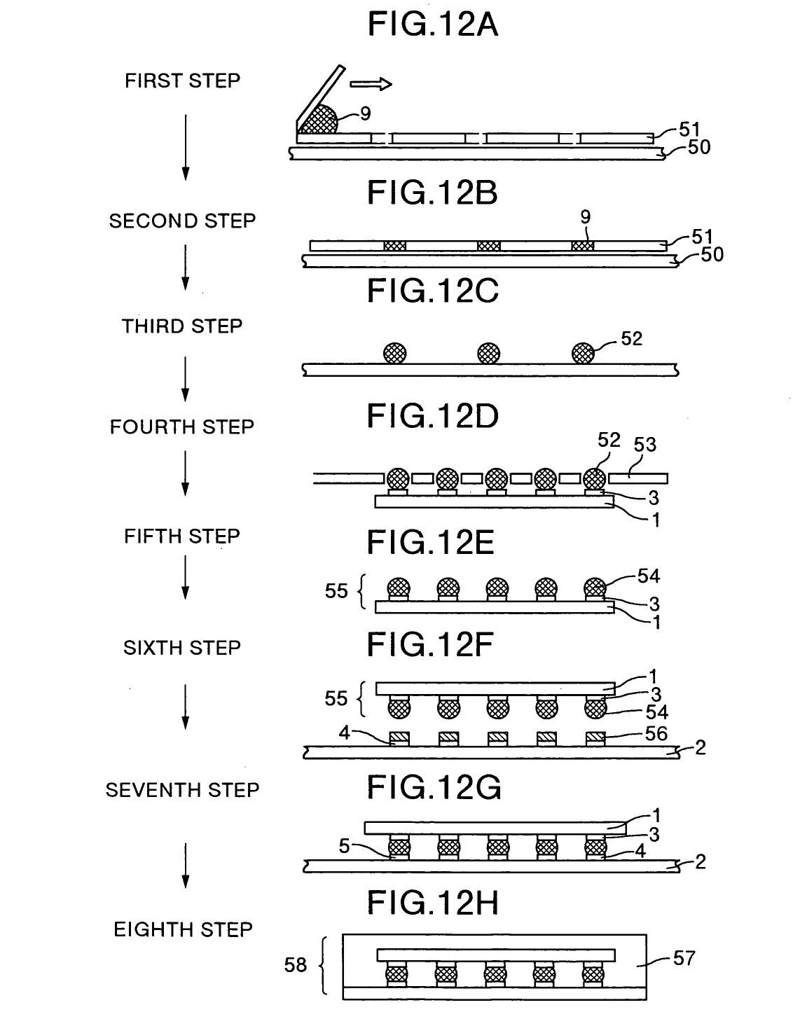

Further, it is also possible to heat these mixed pastes 9 and transform them into a spherical shape in different places beforehand, and supply these spheres, each of which has become an assembly of metallic balls and solder, to the pad separately. This step is shown in FIG. 12. In a first step, a mask 51 is used for a substrate 50 which does not get wet by the solder, the mixed paste 9 is printed and heated in a second step to obtain spheres 52 of the set of the mixed paste (third step). In a fourth step, these are supplied to the pad 3 of the semiconductor chip 1 using an arrangement jig 53, etc., then heated to obtain a semiconductor chip 55 with bumps 54 (fifth step). In a sixth step, this semiconductor chip 55 is mounted on the intermediate substrate 2 which has been subjected to surface treatment 56 so as to enable the bumps 54 to be connected, for example, subjected to application of receiving solder or Au plating, and then heated in a seventh step, and then molded with resin 57 in an eighth step to obtain a mounting structure 58.

Further, it is also possible to apply solder plating, etc., of Sn, etc., to a surface of a metal fine line of Cu, etc., and cut this into small pieces to make those into a paste instead of the metallic balls 6 and solder balls 10, and then print and supply those using a dispenser, etc. Furthermore, it is also possible to conduct Sn plating, etc., onto the surface of a Cu foil, punch it out into a disk shape, supply the disks separately or use them transformed into pastes.

For the pad of the substrate, it is possible to provide treatment such as Sn plating, Sn alloy plating, Au flash plating and Ag plating, etc., to improve wettability. Further, it is also possible to supply mixed pastes to the pad of the substrate by means of printing and dispenser, etc. Supplying solder pastes with solder using Sn or a Sn alloy, etc., to the pad on the substrate also is effective to improve the wettability.

### Embodiment 3

If fine particles or Cu powder of dendrite crystals are mixed with Sn solder having a quasi-equal diameter thereto in an inert atmosphere, and press-molded at a room temperature, it is possible to obtain composite solder with no void. This can be processed into a disk shape or rectangular shape. Since Sn constituting solder balls is not melted in this condition, Cu and Sn remain without being reacted and are freely movable at a temperature of 232° C. or higher at which Sn is melted, at a time of soldering. Further, it is also possible to disperse these particles uniformly, place them on a metal mask adjusted to the terminal pitch beforehand, and position them on the Si chip terminal to supply them. Furthermore, it is also possible to uniformly disperse low heat expansion quartz, invar, etc., subjected to surface treatment to as to cause the surface thereof to get wet with Sn.

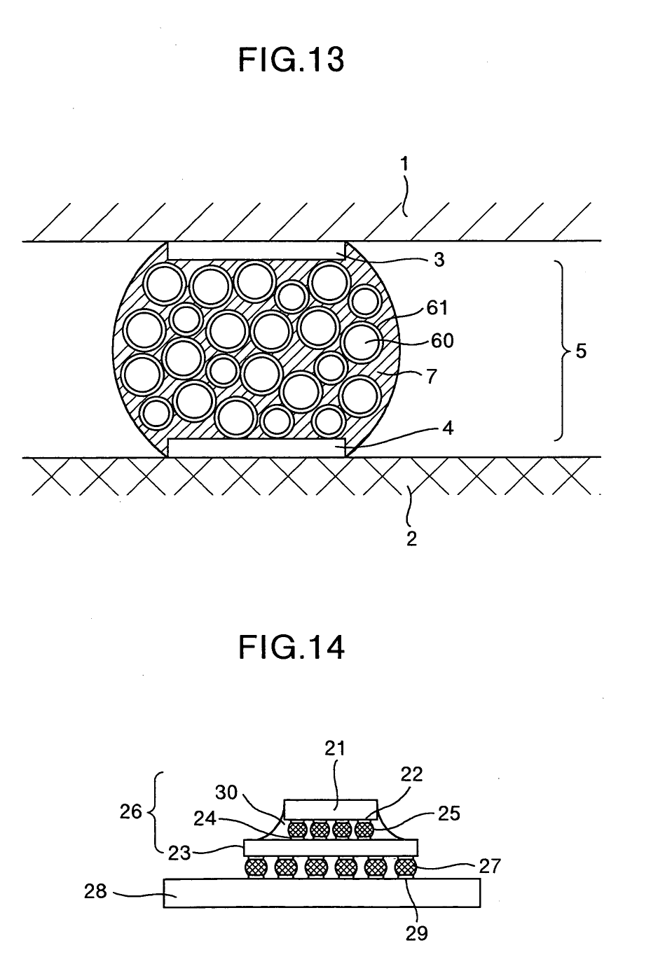

Further, to make it softer, it is also possible to uniformly disperse heat-resistant polymer beads, etc., of approximately 1 μm which are subjected to the surface treatment so as to cause the surface thereof to get wet with Sn. The effect of rubber of these polymer beads, etc., improves impact resistance and temperature cyclicity resistance and leads to an extension of life. Especially, reduction of stress burden on the terminals of the Si element is significant. FIG. 13 shows a model sectional view after connecting, which uses polymer beads as metallic balls. It shows the connecting portion with Ni plating applied to the polymer beads 60 and an Au plated surface treated layer 61 further applied thereto, and heated with Sn solder. At this time, Au is dispersed into the solder to form Au—Sn compounds and further, Sn reacts with Ni to form Ni—Sn compounds in 7, which causes the connecting portion 5 to have a high melting point and be connected.

Packaging of a CSP or flip chip, etc., is often used for mobile products, etc. For this reason, it is possible to secure high reliability by filling with resin having appropriate physical properties after connection. The thermal expansion coefficient of resin ranges from 15 to 40×10⁻⁶/° C. and is preferably 20×10⁻⁶/° C. which is close to that of a bump. Its Young's modulus is 100 to 2000 kgf/mm² and preferably 400 to 1000 kgf/mm² to reduce influences on the element.

### Embodiment 4

FIG. 14 shows an example of a case where a temperature hierarchy connection is performed using the pad configuration of the present invention. This is a connected structure 26 obtained by connecting 25 a pad 22 of a Si chip 21 and a pad 24 of an intermediate substrate 23 called “interposer” by using metallic balls, solder and its compounds. This connected structure 26 is connected to a pad 29 of a glass epoxy substrate 28 using Sn—Ag—Cu system solder 27 (e.g., Sn-3Ag-0.5Cu (melting point: 221 to 217° C.)) having a melting point of approximately 220° C. When the connected structure 26 is connected to the glass epoxy substrate 28, soldering is performed so that the ultimate temperature of the connecting portion became 235° C. in a nitrogen reflow oven. At this time, the connecting portion 25 of the connected structure 26 can maintain its connected state at a temperature higher than the temperature when the connecting portion is formed and remained stable without remelting or peeling.

At this time, if the connecting portion 25 according to the present invention cannot withstand stress produced between the Si chip 21 and intermediate substrate 23, it is also possible to enclose resin 30 between the Si chip 21 and intermediate substrate 23 to disperse the stress produced in the connecting portion 25.

In addition to the Si chip 21, it is also possible to connect a plurality of chips or chip parts, etc., together, on the intermediate substrate 23 using the method of the present invention to provide a module having one function.

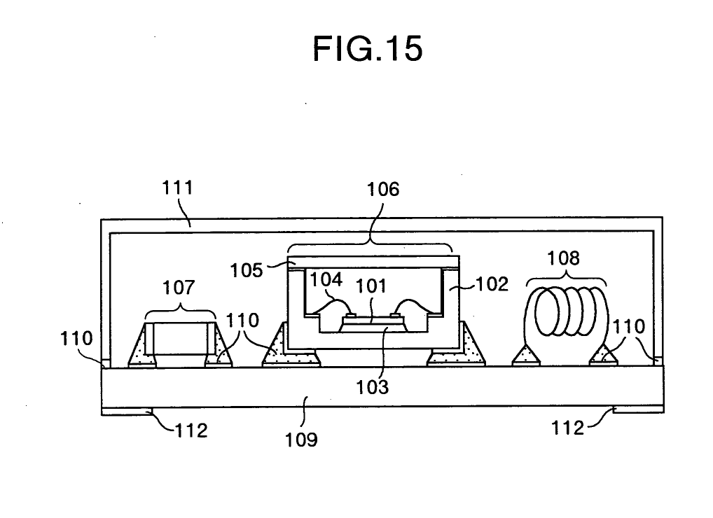

FIG. 15 shows an example where the present invention is applied to an RF module. A semiconductor chip 101 of LT (lithium tantalate), etc., called as a “SAW filter” is connected to a ceramic circuit substrate 102 by a conductive adhesive 103 and wire bonding 104, so that a cover 105 is provided to protect the semiconductor chip. This module 106 together with a chip part 107 and coil part 108, etc., are connected to the intermediate substrate 109 of glass epoxy, etc., and it is possible to realize this connection 110 using a mixed paste of metallic balls and solder. At the same time, the overall cover 111 can also be connected to the intermediate substrate 109. Since the connecting portion 110 has come to have a high melting point because of reaction between solder and metallic balls, it is possible to connect the connecting portion 110 to a motherboard by means of other solder using the pad 112 of the intermediate substrate.

### Embodiment 5

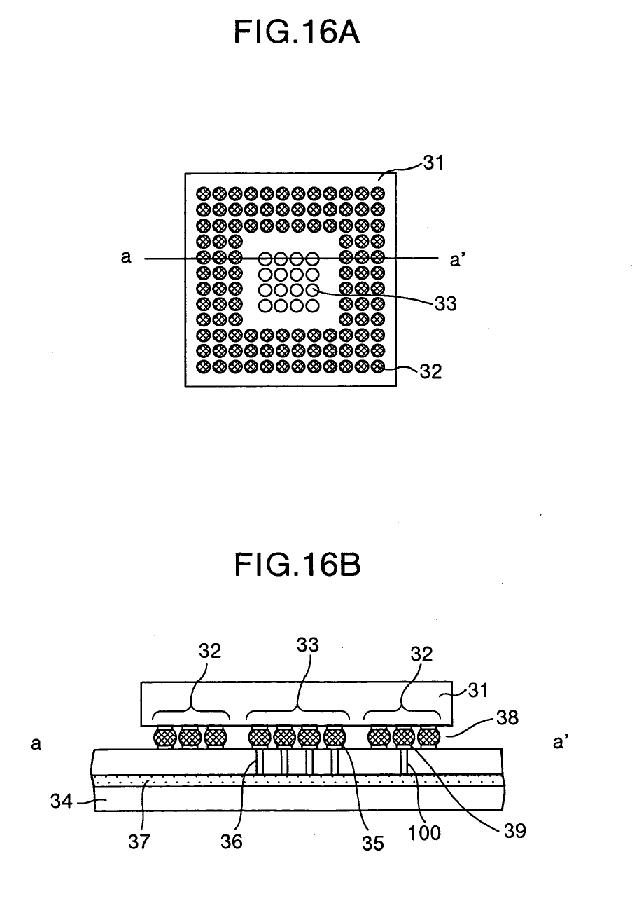

FIG. 16 shows another example of a case where pads are connected together, using a connecting portion of the present invention. This is an example where a metallic heat spread route is created in a substrate to have a structure to allow heat to dissipate. FIG. 16A is a view of the pad viewed from right above a Si chip 31. In this example, signal pads 32 are placed in three rows in the outer regions of the Si chip 31, and inner pads operate as heat spread pads 33 attached to spread the heat. With regard to the connecting portion of this Si chip 31 to the substrate 34, a sectional view along a line a-a′ in FIG. 16A is shown in FIG. 16B. Thermal vias 36 are formed in contact with pads 35 on the substrate 34 side corresponding to the heat spread pads 33. These thermal vias 36 are connected to a metal core layer 37 inside the substrate 34. Both the signal pads 32 and heat spread pads 33 are created using the present invention, and Cu is used for the metallic balls, and Sn-3Ag is used for the solder. Here, the thermal conductivity of solder is approximately 55 W/mK and approximately 36 W/mK for Sn-37Pb and Pb-5Sn solder respectively, while the thermal conductivity of Cu is approximately 390 W/mK, and therefore the connecting portion 38 containing more Cu has higher thermal conductivity than that of the conventional connecting portion using solder. Further, it is also possible to spread the heat from the pad of the connecting portion 38 with good heat diffusion to the metal core layer 37 through the thermal vias 36. Therefore, the connection according to the present invention provides active heat conduction and heat diffusion through the connecting portion 38, and can therefore be said to be an excellent method for mounting a high power chip.

Here, it may be possible to connect a ground pad 39 of the signal pads 32 to the metal core layer 37 of the substrate 34 by forming a via 100. That is, the metal core layer 37 can also serve as the ground of the substrate. Further, the thermal vias 36, metal core layer 37 and via 100 are formed using Cu, but Al, etc., can also be used therefor. On the contrary, it is also possible to select the material of the metallic balls 6, thermal vias 36 and metal core layer 37 so that sufficient performance of the Si chip 31 (LSI) can be obtained.

As described above, the present invention can improve the heat conductivity drastically by means of the material of the metallic balls 6 compared to the usual solder connection, and therefore the present invention is also suitable for high power connection of a Si chip or fine pitch connection with LSI from the standpoint of protecting the performance of the Si chip (LSI). As a specific example, the present invention is suitable for a connecting structure of electronic devices, etc., mounted in an automobile. Further, in the case of the RF module shown in FIG. 15, the frequency may be shifted by heat, and it is therefore important to provide a connecting portion with a good heat spread characteristic for such a product from the standpoint of protecting the performance of the module. Furthermore, as in the case of this embodiment, the pad structure of the present invention can be used not only as the signal pad but also as the pad for heat spread. It is further effective to use it together with the substrate, etc., having the metal core layer to provide heat spread effect.

According to the above described embodiments, it is possible to supply an alternate material for high lead containing solder having a large proportion of lead with a high melting point which has been conventionally used for manufacturing electronic devices. When this material is used, connection can be performed at a low temperature, and the connecting portion after the connection can maintain its connected condition at a temperature higher than the temperature when the connecting portion is formed, so that a temperature hierarchy connection using Sn—Ag—Cu-based Pb-free solder having a melting point of 220° C., etc is allowed. Further, it can also provide a pad configuration capable of withstanding stress or strain generated at the pads due to differences in thermal expansion coefficients of parts and substrate materials. Furthermore, using this pad configuration can reduce environmental impact. Having a structure containing large proportions of metals with high heat conductivity provides active heat conduction and heat diffusion through bumps, and thus an excellent method of mounting high power chip is provided.

According to the present invention, it is possible to provide an alternate material for lead-rich solder with a high melting point which has been used for pads in an electronic component, a connection method and an electronic device using this solder. The present invention can especially provide a lead-free material used for barrel-shaped pads, etc., called as “C4 connection”, and a connection method using this material.

It should be further understood by those skilled in the art that although the foregoing description has been made on embodiments of the invention, the invention is not limited thereto and various changes and modifications may be made without departing from the spirit of the invention and the scope of the appended claims.

1. An electronic device comprising:
an electronic component;
a substrate; and
a connecting portion between a pad of the electronic component and a pad of the substrate, wherein
the connecting portion is composed of metallic ball phases including a single metal, an alloy, a chemical compound, or a mixture thereof, and a phase made of Sn or In, by which phase said metallic ball phases are connected.

2. An electronic device comprising:
an electronic component;
a substrate; and
a connecting portion between a pad of the electronic component and a pad of the substrate, wherein
the connecting portion is composed of metallic ball phases including a single metal, an alloy, a chemical compound, or a mixture thereof, a solder phase made of Sn or In, and an intermetallic compound phase produced by reaction between the metallic ball phases and the solder phase, wherein said metallic ball phases are connected by said intermetallic compound phase, or by said intermetallic compound phase and said solder phase.

3. An electronic device comprising:
an electronic component;
a substrate, and
a connecting portion between a pad of the electronic component and a pad of the substrate, wherein
the connecting portion is composed of metallic ball phases including a single metal, an alloy, a chemical compound, or a mixture thereof, and at least one phase selected from a group of Sn—Cu system solder, Sn—Ag system solder, Sn—Ag—Cu system solder, or solder based on those to which at least one of In, Zn and Bi is added, wherein said metallic ball phases are connected by said at least one phase.

4. An electronic device comprising:
an electronic component;
a substrate; and
a connecting portion between a pad of the electronic component and a pad of the substrate, wherein
the connecting portion is composed of metallic ball phases including a single metal, an alloy, a chemical compound, or a mixture thereof, at least one solder phase selected from a group of Sn—Cu system solder, Sn—Ag system solder, Sn—Ag—Cu system solder, or solder based on those to which at least one of In, Zn and Bi is added, and an intermetallic compound phase produced by reaction between said metallic ball phases and said solder phase, wherein said metallic ball phases are connected by said intermetallic compound phase and/or said solder phase.

5. The electronic device according to any one of claims 1 to 4, wherein each of said metallic ball phases includes at least one selected from a group of Cu, Ag, Au, Al, Ni, Cu alloy, Cu—Sn compound, Ag—Sn compound, Au—Sn compound, Al—Ag compound, Zn—Al compound, and a mixture thereof.

6. The electronic device according to any one of claims 1 to 5, wherein each of said metallic ball phases comprises a core and at least one coat selected from a group of: single metal layers of an Au layer, an Ag layer and Sn; an alloy layer including Sn; an Ni layer bonded to the core and Au layer bonded to the Ni layer; and an Ni layer bonded to the core and an Ag layer bonded to the Ni layer.

7. An electronic device, characterized in that connection between a pad of an electronic component and a pad of a substrate includes the steps of:
providing a paste obtained by mixing metallic balls including a single metal, an alloy, a chemical compound or a mixture thereof with a solder ball including Sn or In between said pads; and
heating said paste to melt said solder ball component so as to connect said metallic balls, said metallic balls and the pad of said electronic component, and said metallic balls and the pad of said substrate.

8. An electronic device characterized in that connection between a pad of an electronic component and a pad of a substrate includes the steps of:
providing a paste obtained by mixing metallic balls including at least one selected from a group of a single metal, an alloy, a chemical compound, or a mixture thereof, and at least one selected from a group of Sn—Cu system solder, Sn—Ag system solder, Sn—Ag—Cu system solder, and solder based on those to which at least one of In, Zn and Bi is added between said pads; and
heating said paste to melt said solder ball component so as to connect said metallic balls, said metallic balls and the pad of said electronic component, and said metallic balls and the pad of said substrate.

9. The electronic device according to claim 7 or 8, wherein each of said metallic balls includes at least one selected from a group of Cu, Ag, Au, Al, Ni, Cu alloy, Cu—Sn compound, Ag—Sn compound, Au—Sn compound, Al—Ag compound, Zn—Al compound, and a mixture thereof.

10. The electronic device according to any one of claims 7 to 9, wherein each of said metallic balls is coated by a coat selected from a group of Au plating, Ag plating, Sn single metallic plating, alloy plating including Sn, two-layer plating with Ni plating applied to a base and Au plating applied to the surface of the Ni plating, and two-layer plating with Ni plating applied to a base and Ag plating applied to the surface the Ni plating.

11. The electronic device according to any one of claims 1 to 5, wherein said connecting portion has one shape selected from a group of a barrel shape, a columnar shape, a rectangular parallelepiped shape and a waist shape.

12. The electronic device according to any one of claims 1 to 11, wherein the substrate of said electronic device includes a metal core layer.

13. A mounting structure comprising the electronic device according to any one of claims 1 to 12 mounted on another substrate by using Pb-free solder.
